(19) United States
(12) Patent Application Publication
(10) Pub. No.: US 2026/0311796 A1
(43) Pub. Date: Oct. 8, 2026

(54) MEMORY SHIFTING CIRCUIT

(71) Applicant: Taiwan Semiconductor Manufacturing Company, Ltd., Hsinchu (TW)

(72) Inventors: Atul KATOCH, Kanata (CA); Cormac Michael O'CONNELL, Carp (CA)

(21) Appl. No.: 19/283,873

(22) Filed: Jul. 29, 2025

Related U.S. Application Data
(60) Provisional application No. 63/782,979, filed on Apr. 3, 2025.

(51) Int. Cl. G11C 29/00; G11C 7/10; G11C 29/02

(52) U.S. Cl. CPC G11C 29/76; G11C 7/1012; G11C 29/022

(57) ABSTRACT

An example memory device includes a repair cell in a repair column having a repair local bit line, a repair local input/output (LIO) circuit having an input connected to the repair local bit line and an output connected to a repair global bit line, and a plurality of memory cells arranged in a first plurality of columns. The memory device further includes a memory LIO circuit and a first global input/output (GIO) circuit having a first multiplexer with a first input connected to the memory global bit line, a second input connected to receive the output of the repair LIO circuit, an output terminal, and a select signal terminal. The first GIO circuit further includes a first compare circuit.

### CROSS-REFERENCES TO RELATED APPLICATIONS

The present application claims the benefit of U.S. Provisional Application No. 63/782,979 filed Apr. 3, 2025, the disclosure of which is hereby incorporated by reference in its entirety.

### BACKGROUND

A common type of integrated circuit memory is a static random-access memory (SRAM) device. A typical SRAM memory device has an array of memory cells. Further, each SRAM memory device includes memory cells organized in columns. The memory cells connect to a local input/output (LIO) through a bit line. The LIO may include a sense amplifier. The LIO connects to a global input/output (GIO) through a global bit line. The GIO the connects to an output of the memory device for providing data bits to other components such as a central processing unit (CPU).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a block diagram of an example memory device in accordance with disclosed embodiments.

FIG. 2 is a block diagram illustrating an example memory cell of the memory device of FIG. 1 in accordance with disclosed embodiments.

FIG. 3 is a block diagram illustrating further details of the memory device of FIG. 1.

FIG. 4 is a block diagram illustrating an example embodiment of a GIO of the memory device of FIG. 1 in accordance with disclosed embodiments.

FIG. 5 is a block diagram illustrating an example embodiment of an GIO controller and a repair IO controller of FIG. 2.

FIG. 6 is a timing diagram showing example signals generated by components within the memory device of FIG. 1.

FIG. 7 is a block diagram illustrating an example method for repairing a memory cell of the memory device of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some memory devices are constructed of memory cell arrays connected to a row decoder via word lines. Additionally, the memory cell array contains local bit lines connecting the columns of a plurality of memory cells to a local Input/Output (IO) block. Thus, the bit lines of each column are respectively coupled to a plurality of memory cells that are disposed in that column, and each memory cell in that column is arranged on a different row and coupled to a respective word line. Typically, the bit lines extend in one direction (parallel to a first axis) and the word lines extend in a second direction (parallel to a second axis) perpendicular to the first direction.

Global bit lines connect the LIO block to a GIO block. The LIO block and the GIO block are connected to a local control and a global control which implement the control logic of the memory device.

A sense amplifier in the LIO receives the bit line signals and amplifies them for use in logic components. The signals from the sense amplifier pass the data from the LIO to the GIO along the global bit lines. In some examples, data on the global bit line is latched, and the latch is set before the sense amplifier stops driving the global bit line to maintain the global bit line output for a sufficient time period.

Memory devices include repair components if a component fails. For example, a memory device may include a repair column, a repair memory cell, a repair LIO, a repair GIO, or any combination. A repair column, repair memory cell, repair LIO, or repair GIO may sometimes be referred to as a redundant column, redundant memory cell, redundant LIO, or redundant GIO and may be used interchangeably. When a component fails, the data or address of the failed component can be transferred to the repair component. Many memory devices use an entire repair component. For example, a repair LIO includes the same components as a regular operation LIO, including all necessary components for column select or transmission on a global bit line. In some cases, this can lead to an increased chip-area-usage of 1-2%.

The present disclosure provides a memory device that reduces the number of columns used for a repair LIO circuit. For example, rather than use an entire memory array having 16 columns connected to a LIO circuit, a single repair column (or small number of columns) may be used. Since only a single repair column is used, the repair LIO circuit may not require a column select, facilitating a smaller, simpler LIO circuit. In some disclosed examples, a shifting circuit is then used to “shift” the data from the repair memory cells to the desired GIO.

Each of the GIO circuits of the memory device include the shifting circuits for repairing failed columns. To form the shifting circuits, the repair GIO circuit is connected to a repair LIO circuit. The repair GIO circuit connects to a multiplexer of an adjacent first GIO circuit. In some embodiments, the multiplexer of the first GIO circuit then connects to a second multiplexer of an adjacent second GIO circuit. This connection allows data to be transferred based on repair addresses without increased use of the area of the memory device. Corresponding compare circuits within each shifting circuit of the GIO circuits provide a SELECT signal to the multiplexer to determine whether to provide the corresponding LIO data bit or the adjacent GIO circuit.

The memory device with the shifting circuit can utilize repair components with reduced area usage. Further, a column address signal may be provided to the shifting circuit of each GIO circuit. In some embodiments, the column address signal enables each of the GIO circuits to shift which data bit is transmitted to the output terminal of the memory device. In some embodiments, the shifting circuit and a HIT signal can be used to transform a static shift to a dynamic shift for redundancy. The HIT signal includes the address of the GIO circuit that corresponds to the failed column select (i.e., the failed GIO address) provided to the compare circuits, which causes them to provide the select signal. In some embodiments, the HIT signal is used to ensure proper timing of reading the bits. The memory device uses the shifting circuit to select a repair column associated with a repair LIO circuit and a repair GIO circuit that include a smaller area. That is, the shifting circuit enables the GIO circuit associated with the failed memory column to output the data bit now stored at the repair memory column. By implementing the shifting circuit with the GIOs, the repair LIO can be added with fewer components. In some embodiments, the repair LIO circuit can be reduced to one, two, three, or four columns of the memory device.

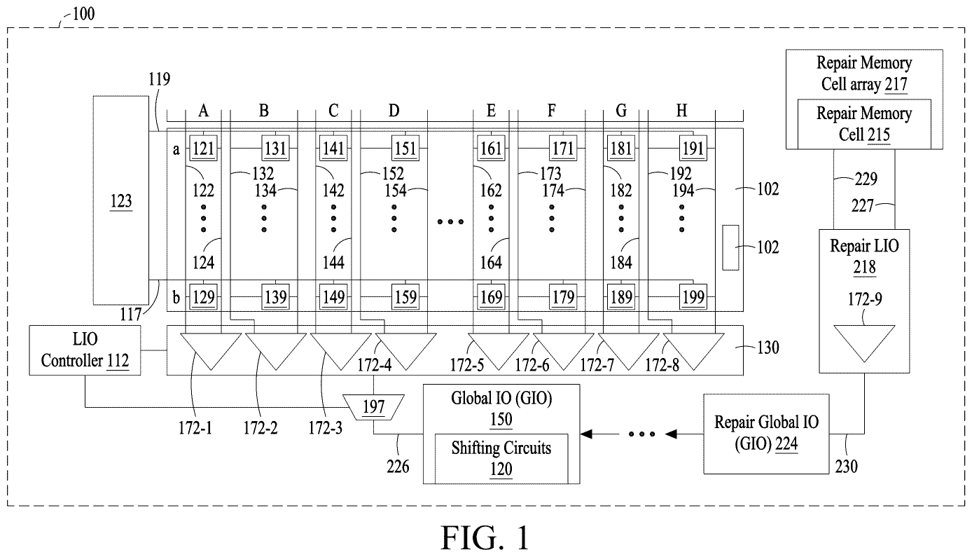

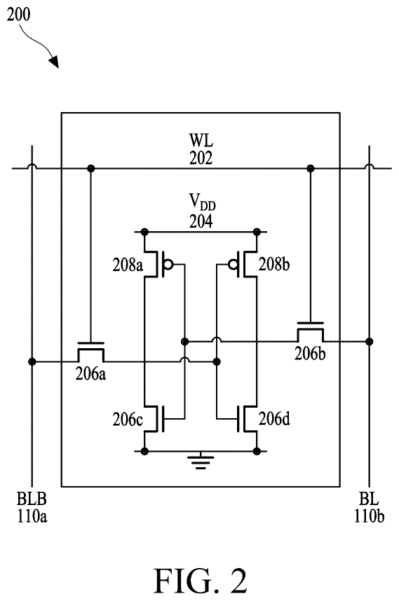

FIG. 1 illustrates aspects of the memory device 100. In some embodiments, the device 100 includes a memory cell array 102, which may be an SRAM array employing a plurality of SRAM memory cells, such as a memory cell 200 shown in FIG. 2 and further discussed below. However, the memory cell array 102 may be implemented as any of a variety of memory cell arrays (e.g., DRAM, MRAM, RRAM etc.) while remaining within the scope of the present disclosure. For example, the memory cell array 102 may be implemented as a read-only-memory (ROM) array, a logic n-type metal-oxide-semiconductor (NMOS) array, a logic p-type metal-oxide-semiconductor (PMOS) array, or a combination thereof.

Referring still to FIG. 1, as described above, the SRAM memory cell array 102 includes a plurality of SRAM memory cells (e.g., 121, 129, 131, 139, 141, 149, 151, 159, 161, 169, 171, 179, 181, 189, 191, 199) arranged in a column-row configuration. For clarity, the SRAM memory cell is referred as “cell” hereinafter. Although the illustrated embodiment of FIG. 1 shows only 16 cells, any desired number of cells may be included in the embodiment of memory device 100 while remaining within the scope of the present disclosure. More specifically in the memory cell array 102, cells 121 and 129, and any other cells disposed therebetween are arranged in column “A”. Similarly, cells 131 and 139, and any other cells disposed therebetween are arranged in column “B;” cells 141 and 149, and any other cells disposed therebetween are arranged in column “C;” cells 151 and cells 159, and any other cells disposed therebetween are arranged in column “D;” cells 161 and 169, and any other cells disposed therebetween are arranged in column “E;” cells 171 and 179, and any other cells disposed therebetween are arranged in column “F;” cells 181 and 189, and any other cells disposed therebetween are arranged in column “G;” cells 191 and 199, and any other cells disposed therebetween are arranged in column “H.” Although only 8 columns are illustrated, any desired number of columns may be arranged between the columns D and E. In each column, any desired number of cells may be disposed between the illustrated cells. For example, in column A, one or more cells may be disposed between the cells 121 and 129. The cells in each column are each disposed in a respective row, and each row may include a plurality of cells that each belong to a respective, and different column. In the illustrated embodiment, the cells 121, 131, 141, 151, 161, 171, 181, and 191 that belong to column A, B, C, D, E, F, G, and H, respectively, are disposed in a same row, hereinafter row “a.” Similarly, the cells 129, 139, 149, 159, 169, 179, 189, and 199 that belong to column A, B, C, D, E, F, G, and H, respectively, are disposed in a same row, hereinafter row “b.” Although only 2 rows are illustrated, any desired number of rows may be arranged between the rows a and b.

As described above, each column has a respective pair of complementary bit lines (BL, BLB) that are coupled to the cells in that column, and each row has a respective word line that is coupled to multiple cells that respectively belong to multiple columns. For example, as illustrated in the SRAM cell array 102, column A has BL 122 and BBL 124; column B has BL 132 and BBL 134; column C has BL 142 and BBL 144; column D has BL 152 and BBL 154; column E has BL 162 and BBL 164; column F has BL 173 and BBL 174; column G has BL 182 and BBL 184; column H has BL 192 and BBL 194. The cells of each column are coupled to the column's BL and BBL. For example, the cells 121 and 129, and any cells coupled therebetween are each coupled to the BL 122 and BBL 124; the cells 131 and 139, and any cells coupled therebetween are each coupled to the BL 132 and BBL 134; the cells 141 and 149, and any cells coupled therebetween are each coupled to the BL 142 and BBL 144; the cells 151 and 159, and any cells coupled therebetween are each coupled to the BL 152 and BBL 154; the cells 161 and 169, and any cells coupled therebetween are each coupled to the BL 162 and BBL 164; the cells 181 and 189, and any cells coupled therebetween are each coupled to the BL 182 and BBL 184; the cells 191 and 199, and any cells coupled therebetween are each coupled to the BL 192 and BBL 194. Further, the cells 121, 131, 141, 151, 161, 171, 181, and up to 191 arranged in the row a are each coupled to the word line 119 of row a; and the cells 129, 139, 149, 159, 169, 179, 189, and up to 199 arranged in the row b are each coupled to the word line 117 of row b.

The row decoder 123 is coupled to all the word lines of the SRAM cell array 102. In some embodiments, the row decoder 123 is configured to receive a row address (as described above) and based on the row address, to assert the word line at the row address so as to activate one or more access transistors coupled to the word line.

Each of the bit lines BL/BLB are connected to a local IO circuit 130 (LIO circuit). The local IO circuit 130 includes a plurality of the sense amplifiers 172-1, 172-2, 172-3, 172-4, 172-5, 172-6, 172-7, and up to 172-8. Each of the sense amplifiers of the local IO circuit 130 is coupled to the BL and BBL of one single column. For example, the sense amplifier 172-1 is coupled to the BL 122 and BBL 124 of column A; the sense amplifier 172-2 is coupled to the BL 132 and BBL 134 of column B; the sense amplifier 172-3 is coupled to the BL 142 and BBL 144 of column C; the sense amplifier 172-4 is coupled to the BL 152 and BBL 154 of column D; the sense amplifier 172-5 is coupled to the BL 162 and BBL 164 of column E; the sense amplifier 172-6 is coupled to the BL 173 and BBL 174 of column F; the sense amplifier 172-7 is coupled to the BL 182 and BBL 184 of column G; and the sense amplifier 172-8 is coupled to the BL 192 and BBL 194 of column H. Operatively, such sense amplifiers of the local IO circuit 130 are each configured to compare a voltage difference between the coupled BL and BBL to which a cell is coupled so as to read bit data stored in that cell. As a representative example, if the bit data stored in the cell 121 is a logical 1, the sense amplifier 172-1 may read a logical 1 based on the comparison of the voltage difference between the coupled BL 122 and BBL 124.

In some embodiments, the memory cell device 100 includes a repair memory cell array 217. Manufacturing memory devices may result in defects. The defects can result in one or more memory cells not properly functioning. The memory device 100 can be programmed to use another memory cell or a repair memory cell 215 instead of the failed memory cell. In some embodiments, the data bits that would be stored in the failed memory cell are configured to be stored in the repair memory cell 215.

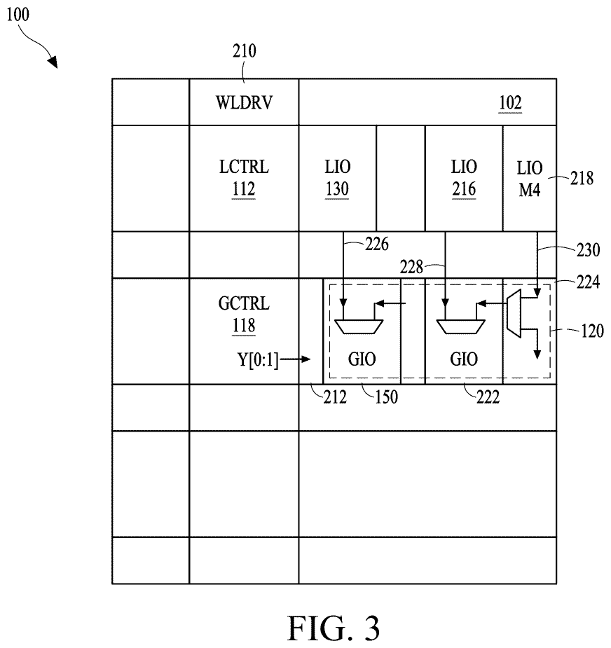

The LIO circuit 130 is controlled by the centrally located LIO controller 112 (discussed in relation to FIG. 3). The signals from the bit lines, such as the BL 122 and the bit line 124, converge on the LIO circuit 130 and are combined in the LIO circuit 130. The LIO circuit 130 outputs the LIO signal to a global bit line 226. Latch circuits are configured to latch the global bit line signal on the global bit lines 226 in response to the LIO signal output from the LIO circuit 130. The GIO circuit 150 receives the global bit line signal from the global bit lines 226 to output a GIO signal. In the illustrated example, the GIO circuit 150 is controlled by the centrally located GIO controller 118 (discussed in relation to FIG. 3). In some embodiments, the LIO circuit 130 includes a column select. The column select may include a multiplexer. For example, the column select multiplexer may connect to each sense amplifiers 172-1, 172-2, 172-3, 172-4, 172-5, 172-6, 172-7, and 172-8. The column select multiplexer can then select a corresponding memory cell column to output on the global bit line 226. In some embodiments, the plurality of sense amplifiers 172 may include a terminal to receive a sense amplifier enable signal (SAE). Each of the sense amplifiers 172-1, 172-2, 172-3, 172-4, 172-5, 172-6, 172-7, and 172-8 connect to a column select 197. The column select 197 may include a multiplexer. In some embodiments, the column select 197 selects one sense amplifier of the sense amplifiers 172-1, 172-2, 172-3, 172-4, 172-5, 172-6, 172-7, and 172-8 to output on the global bit line 226. The column select 197 may connect to the LIO controller 112 to receive a select signal that indicates which sense amplifier to output to.

In some embodiments, the memory device 100 includes a plurality of LIO circuits in addition to the LIO circuit 130. In some embodiments, the LIO circuits may include a repair LIO that connects to the repair memory cell. Further, the GIO circuit 150 may include a plurality of GIO circuits connected to different LIO circuits. The plurality of GIO circuits includes a repair GIO. The repair GIO connects to the repair LIO as shown in FIG. 3. The repair LIO and the repair GIO can be used repair a failed memory cell. Further, the GIO circuit 150 includes shifting circuits 120 for dynamically shifting the output of the GIO circuit 150 to a different GIO circuit. The shifting circuits 120 enables the use of different memory cell columns, such as a repair memory cell column, when the memory device 100 attempts to read a failed address associated with the GIO circuit 150.

In some embodiments, the memory device 100 uses a memory cell associated with a different LIO and a different GIO than the failed memory cell. For example, the repair memory cell may be mapped to a repair LIO and a repair GIO. As a result, reading the bit that is mapped to the failed memory cell may require reading output of the repair LIO and the repair GIO as opposed to the original LIO and GIO associated with the failed memory cell.

The repair memory cell array 217 may also be used. During the manufacturing process of integrated circuits, defects are inevitable. These defects can cause individual memory cells or even entire rows or columns of cells within an SRAM array to be faulty. Without redundancy, a single faulty cell could render the entire SRAM chip unusable, leading to a significant decrease in the number of good chips produced from a silicon wafer (i.e., lower yield). By incorporating redundant memory cells (spare rows and/or columns), manufacturers can test the SRAM after production to identify any faulty cells. And they can repair the memory device 100 by disabling the rows or columns containing faulty cells and activating the redundant (spare) rows or columns to take their place. To repair the address, the address pointing to the failed memory cell can be configured to read data stored at a repair memory cell in the repair memory cell array 217, instead. In some embodiments, the repair memory cell array 217 is four columns, three columns, two columns, or one column, rather than a larger standard memory array could include, for example, 16 or more columns.

The repair memory cell array 217 includes the repair memory cell 215 that connects to a repair LIO circuit 218 through a repair bit line 229 and a repair BLB bit line 227. In some embodiments, the repair memory cell array 217 and/or the repair LIO circuit 218 does not include a column select. As a result of lacking the column select, the repair LIO circuit 218 occupies less area than the LIO circuit 130 and the LIO circuit 216. The repair LIO circuit 218 lacks the column select circuit because it is limited to four or less columns of repair memory cells. The repair LIO circuit 218 may include a sense amplifier 172-9. In some embodiments, the repair LIO circuit 218 uses each repair column for reading a word, such as a 4-bit word length, so, a column select is not needed. In some embodiments, the at least one repair memory cell includes four columns, three columns, two columns, or one column. The repair memory cell 215 may be the memory cell 200 shown in FIG. 2.

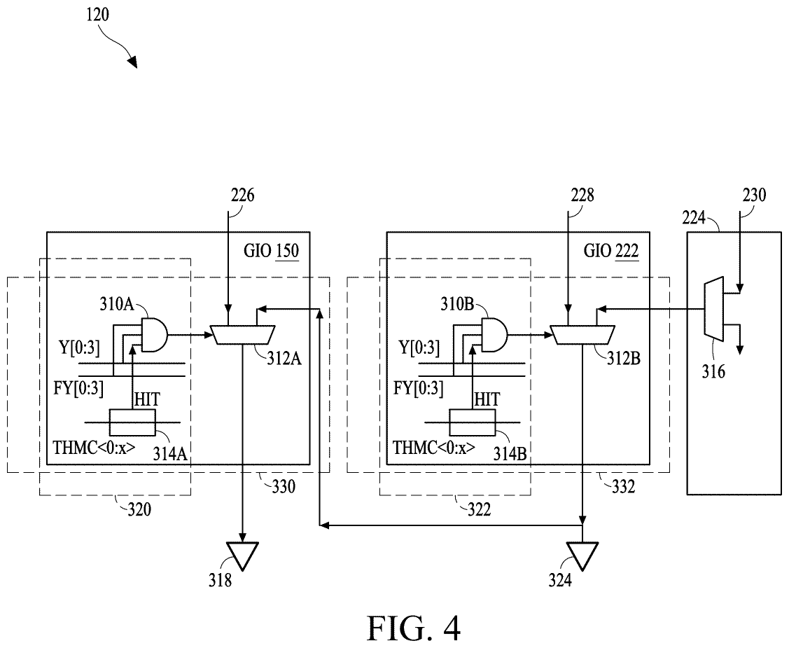

The repair LIO circuit 218 connects to a repair GIO circuit 224 through a repair global bit line 230. The repair GIO circuit 224 connects to an adjacent GIO (discussed in relation to FIG. 3 and FIG. 4). Each GIO then connects to each adjacent GIO, which connects to the GIO circuit 150.

The repair LIO circuit 218 includes similar components to the LIO circuit 130 and the LIO circuit 216. However, the repair LIO circuit 218 lacks a column select, such as the column select 197, that activates an output of a sense amplifier that is connected to a desired column. For example, the number of connected repair memory cell columns may be two. In some embodiments, only one column is used for repair. In some embodiments, four columns of memory cells may be connected to the repair LIO circuit 218 as repair memory cells. The four repair columns or two repair columns may be used in a 16-bit memory device.

FIG. 2 illustrates an example of a memory cell 200 of memory cell array 102. The memory cell 200 shown in FIG. 2 thus illustrates an example of the memory cells 121, . . . shown in FIG. 1. The memory cell 200 is connected to a word line WL 202 and complementary local bit lines BL 110b and BLB 110a. The memory cell 200 includes PMOS transistors 208a-b and NMOS transistors 206a-d. The transistors 208a and 206c are coupled to one another and positioned between a supply voltage V_{DD} 204 and ground to form an inverter. Similarly, the transistors 208b and 206d are coupled between V_{DD} 204 and ground to form a second inverter.

The two inverters are cross coupled to each other. An access transistor 206a connects the output of the first inverter to the bit line BLB 110a. Similarly, the access transistor 206b connects the output of the second inverter to the bit line BL 110b. The word line WL 202 is attached to the gate controls of the access transistors 206a and 206b to selectively couple the outputs of the inverters to the bit lines (110a, 110b) during read/write operations. During a read operation the inverters drive the voltage levels at the bit lines (110a, 110b) high and low.

The cross coupled inverters of the memory cell 200 provide two stable voltage states denoting logic values 0 and 1. Metal-Oxide Semiconductor Field Effect Transistors (MOSFETs) are typically used as the transistors in FIG. 2B. In some embodiments more or fewer than 6 transistors may be used to implement the memory cell 200.

FIG. 3 illustrates further details of the memory device 100. Here, the memory device 100 also includes a word line driver 210, a LIO circuit 130, a LIO circuit 216, a repair LIO circuit 218, a global bit line 226, a global bit line 228, a repair global bit line 230, a repair IO controller 212, a GIO circuit 150, a GIO circuit 222, and a repair GIO circuit 224.

The word line driver 210 and connected word lines are used to select and access specific memory cells (as shown in FIG. 1). For example, the word line driver 210 is connected to the word line 119 and the word line 117. The word line selects a specific row of memory cells within a memory array. When a particular word line is activated (energized, usually by applying a specific voltage), it enables all the memory cells connected to it in that row. This allows data to be read from or written to the cells in the selected row. Only one word line is typically active at any given time to ensure that the correct memory cells are being accessed. Word lines often run perpendicular to bit lines (which are typically the vertical lines in the grid). The intersection of a word line and a bit line usually pinpoints the location of a single memory cell. When a word line is activated, the selected memory cells can then share their data with their respective bit lines for a read operation or receive data from the bit lines for a write operation.

The word line driver 210 activates and deactivates selected word lines. Also, the word line driver 210 may receive and decode address signals (which specify which row of memory cells to access) and provides the necessary voltage or current to the selected word line. In some embodiments, the word line driver 210 includes the row decoder 123. In some embodiments, the word line driver 210 ensures that only the intended word line is activated and that all other word lines remain in a deselected state (often at a lower voltage or ground) to prevent accidental access or data corruption. Further, the word line driver 210 may operate under precise timing control signals from the memory controller to synchronize its actions with other memory operations. The word line driver 210 may also maintain the integrity of the signal along the word line.

The LIO circuit 130 and the LIO circuit 216 connect to active memory cells of the memory cell array 110 and the memory cell array 116 through corresponding bit lines, such as the BL 122 and the bit line 124 (not shown). The LIO circuit 130 includes an output terminal that connects to the global bit line 226. Also, the LIO circuit 216 includes an output terminal that connects to the global bit line 228. The repair LIO circuit 218 includes an output terminal that connects to the repair global bit line 230. An output terminal of the sense amplifier (shown in FIG. 1) connects to the global bit line 226. The LIO circuit 216 and the repair LIO circuit 218 may include the same or similar components. In some embodiments, the LIO circuit 130 and the LIO circuit 216 may include a latch circuit and other transistors to pass the read data signal to the output terminal connected to the global bit line 226 or the global bit line 228.

In some embodiments, there are additional LIO circuits not shown. For example, each LIO circuit may connect to four columns of memory cells of the memory cell array 102. In some embodiments of this example, there are four LIO circuits in a 16-bit memory device. In another example, each LIO circuit may connect to one or more columns of memory cells of the memory cell array 102. In some embodiments, each LIO circuit is configured to provide multiple bits from multiple columns in a multi-bit word read. In some embodiments of the example, there are eight LIO circuits in a 16-bit memory device.

The GIO circuit 150 and the GIO circuit 222 include terminals for connecting to adjacent GIO circuits. For example, the GIO circuit 150 may include an input terminal that connects to an output terminal of the GIO circuit 222. These terminals can be used to shift the output of the GIO circuit 222 to the GIO circuit 150 in the case of repair. If the GIO circuit 150 corresponds to a failed column, then the output of the GIO circuit 150 is shifted to the GIO circuit 222. The output signal of LIO circuit 216 is transmitted as repair data through the GIO circuit 222 then to the GIO circuit 150. In some embodiments, the output of the GIO circuit 222 is shifted to the output of the repair GIO circuit 224. That is, the GIO circuit 222 outputs the output signal from the repair GIO circuit 224, which provides the output from the repair LIO circuit 218 as data associated with the new address for the stored bit of data. This connection enables a dynamic shift of outputs between the GIO circuits depending on the location of the failed memory cells.

The GIO circuit 150 and the GIO circuit 222 receive bits to be transmitted to other components outside the memory device 100. Additional GIO circuits may be included, though, not shown. For example, the 16-bit memory device may include four GIOs that correspond to four columns. The address for each GIO can include four bits. In some embodiments, the 16-bit memory device may include eight GIOs that correspond to two columns. The address for each GIO can include two bits.

The GIO circuit 150 and the GIO circuit 222 include an output terminal that connects to an output buffer of the memory device 100. Data transmitted to the output buffer can then be transmitted to other components connected to the memory device 100. Also, the GIO circuit 150 and the GIO circuit 222 include an input terminal connected to the global bit line 226 and the global bit line 228, respectively. Further, the GIO circuit 150 and the GIO circuit 222 may include an inverter or other components for processing received data transmissions at the input terminal. In some embodiments, the GIO circuit 150 and the GIO circuit 222 include a circuit to measure the edge of a received clock. The GIO circuit 150 and the GIO circuit 222 may include other components to turn on and off different inverters or other components within. In some embodiments, the GIO circuit 150 and the GIO circuit 222 include additional input terminals that connect to additional global bit lines not shown. These global bit lines may connect to additional LIO circuits not shown. In some embodiments, the output buffer includes an output driver. Further, the shifting circuit includes components within the GIO circuit 150 and the GIO circuit 222 to enable using repair columns that are associated with the repair LIO circuit 218 and the repair GIO circuit 224 for failed memory addresses.

The repair IO controller 212 connects to the GIO circuit 150 and the GIO circuit 222. In some embodiments, the repair IO controller 212 includes input terminals. Further the repair IO controller 212 may connect to additional GIO circuits not shown. The repair IO controller 212 transmits control signals to the GIO circuit 150 and the GIO circuit 222 to enable the dynamic shift of output based on the location of the failed memory cell using the shifting circuits 120.

FIG. 4 illustrates an example embodiment of the shifting circuits 120 of the memory device 100. Here, the GIO circuit 150, the GIO circuit 222, and the repair GIO circuit 224 are shown with connected input/output terminals. The GIO circuit 150 includes a compare circuit 320 and a multiplexer 312A. The GIO circuit 222 includes a compare circuit 322 and a multiplexer 312B that forms a shifting circuit 330. The compare circuit 320 includes an AND gate 310A, and a HIT device 314A that forms a shifting circuit 332. The compare circuit 322 includes an AND gate 310B, and a HIT device 314B. The repair GIO circuit 224 includes a multiplexer 316.

The compare circuit 320, the compare circuit 322, the multiplexer 312A, the multiplexer 312B, and the repair GIO circuit 224 are used to shift output of the corresponding LIO circuit to a different GIO circuit. For example, the GIO circuit 150 may be associated with a failed memory cell column. A memory cell column associated with the GIO circuit 222 is used as a repair column. The output of the GIO circuit 150 is then shifted to the output of the GIO circuit 222 when the memory device 100 attempts to read the data bit originally stored at the failed memory cell column. In some embodiments, bits stored in a failed memory cell column are mapped to a repair memory cell column after scanning for failed components, such as a repair column within the repair memory cell array 217. The memory device 100 can be scanned for failed components during the manufacturing process. In some embodiments, the compare circuit 320 includes different components. For example, the compare circuit 320 can include a NAND gate with reversed polarity for the inputs.

In some embodiments, a failed memory cell column is associated with the GIO circuit 322. Bits that would be stored in the failed memory cell column are then mapped to a repair memory cell column associated with the repair GIO circuit 224. When the memory device 100 accesses the bit that would be stored in the failed memory cell column, the output of the GIO circuit 222 is shifted to output the signal received from the repair GIO circuit 224, which provides the bit from the repair memory cell column.

To shift output, the compare circuit 320 may provide a SHIFT signal to the multiplexer 312A. The multiplexer 312A includes an input terminal connected to the global bit line 226. Further, the multiplexer includes an input terminal that connects to an output of terminal of the multiplexer 312B. The multiplexer also includes an output terminal that connects to an output buffer 318. In some embodiments, the output terminal of the multiplexer 312A also connects to the input of another multiplexer of an adjacent GIO circuit not shown. The multiplexer 312A also includes a select terminal that connects to an output terminal of the AND gate 310A. The AND gate 310A outputs a SHIFT signal that selects either the signal from global bit line 226 or the output from the multiplexer 312B. For example, when the SHIFT signal is high, the multiplexer outputs the signal from the multiplexer 312B. When the SHIFT signal is low, multiplexer outputs the received signal from the global bit line 226.

The multiplexer 312B performs similar functions as the multiplexer 312A and includes similar terminals. The multiplexer connects to an output buffer 324. Though, the multiplexer 312B connects to an output terminal of the multiplexer 316. This connection allows the SHIFT signal from the AND gate 310B to select either the signal received from the global bit line 228 or the signal received from the multiplexer 316. As a result, the multiplexer 312B can output the bit stored in a repair memory cell column associated with the repair GIO circuit 224. Further, the output buffer 318 and the output buffer 324 connect to an output terminal of the memory device 100 to transfer bits to external components. In some embodiments, the repair GIO circuit 224 does not include other components of the shifting circuit, but only the multiplexer 316.

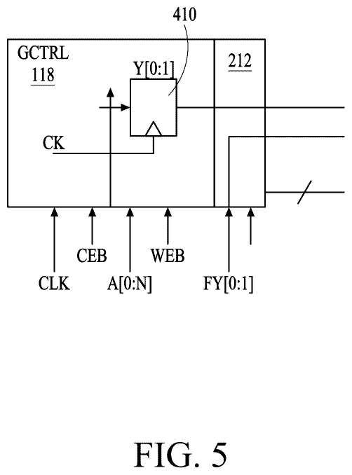

In the shown embodiment, the AND gate 310A includes an input terminal that connects to an output terminal of a flip-flop (shown in FIG. 5) that stores a read operation address. The read operation address indicates the memory cell that is being read. In some embodiments, the read operation address includes two bits Y[0:1]. In some embodiments, the read operation address includes four bits Y[0:3]. The AND gate 310 includes an input terminal that connects to an output terminal of a fail column address flip-flop. The fail column address flip-flop stores an address of a failed memory cell. In some embodiments, the fail column address includes two bits FY[0:1]. In some embodiments, the fail column address includes four bits FY[0:3]. In some embodiments, the flip-flop is within the GIO controller 118 and the fail column address flip-flop is within the repair IO controller 212.

The flip-flop and the fail column address flip-flop may be any kind of flip-flop. For example, the flip-flop and the fail column address flip-flop may be a D flip-flop. In some embodiments, the flip-flop and the fail column address flip-flop are JK flip-flops, T flip-flops, or other kinds of flip-flops. Further, a combination of different flip-flop types may be used.

In some embodiments, the flip-flop includes an input terminal connected to the GIO controller. The flip-flop receives the read operation address from the GIO controller. In some embodiments, the fail column address flip-flop includes an input terminal that connects to the repair IO controller 212. The repair IO controller 212 provides the fail column address to the fail column address flip-flop. In some embodiments, the flip-flop and the fail column address flip-flop are held by the flip-flops until the read is successfully completed.

The HIT device 314A includes an output terminal that connects to the AND gate 310A. In some embodiments, the HIT device 314A provides a HIT signal to the AND gate 310A. In some embodiments, the HIT device 314A includes an input terminal connected to the repair IO controller 212. In some embodiments, the HIT device 314A receives a thermometer decoded output from the repair IO controller 212. The thermometer decoded output is used to select the GIO circuit that has a failed memory cell column. All GIO circuits that are between the GIO circuit associated with the memory cell column that is used to repair the failed memory cell column and the failed memory cell column itself may also receive the thermometer decoded output. For example, the failed memory cell column includes at least one failed memory cell. The GIO circuit 150 is associated with a failed memory cell column. The repair memory cell column associated with the repair GIO circuit 224 and the repair LIO circuit 218 is used to repair. The multiplexer 312A of the GIO circuit 150 will shift output to the output of the multiplexer 312B, while the multiplexer 312B will shift to the output of the multiplexer 316. To cause the shift, the HIT device 314B provides the HIT signal to both the AND gate 310A and the AND gate 310B. In some embodiments, the HIT device 314A is a flip-flop.

In some embodiments, the HIT device 314A only provides HIT signal when the read operation address and fail column address match. In some embodiments, the HIT signal sequentially provides the bits of the address corresponding to the failed GIO one by one. The HIT device 314B includes the same or similar components and performs the same or similar functions as the HIT device 314A. In some embodiments, the output of the HIT device 314A or the HIT device 314B is a sequence of bits that represents an address of the GIO circuit corresponding to the failed memory cell. The address is the same as the read operation address Y[0:1] and the fail column address FY[0:1] when a read operation is attempting to access the failed memory cell that has been repaired. The interpreted signal from the repair IO controller 212 may be the redundancy repair data. In some embodiments, the GIO circuit with the failed memory cell is detected by scanning each of the GIO circuits when the device is manufactured.

In some embodiments, the HIT device 314A and the HIT device 314B are thermometer-to-binary (TM2B) encoders. TM2B encoders are digital circuits responsible for converting the thermometer code (a sequence of ‘1’s followed by ‘0’s, or vice versa, where the number of ‘1’s represents the value) into its equivalent binary representation. These encoders can be implemented using various digital logic components. In some embodiments, the output of the TM2B is a sequence of bits that represents an address of a failed memory cell. For example, the address may be 1001 may be transmitted as THMC<0:x>. In some embodiments, the HIT outputs 1,0,0,1 to the AND gate 310A or the AND gate 310B if the read operation address and the fail column address are also 1001.

FIG. 5 illustrates an example embodiment of the GIO controller 118 and the repair IO controller 212. The GIO controller 118 includes a flip-flop 410. In some embodiments, the flip-flop 410 is a D flip-flop. The GIO controller 118 receives a CLK signal that corresponds to clock. Further, the CLK signal may be used to synchronize the CK signal that is provided as a clock signal to the flip-flop 410. In some embodiments, the flip-flop 410 is the flip-flop that holds the read operation address and provides it to the AND gate 310A. In some embodiments, the GIO controller 118 includes a second flip-flop connected to the AND gate 310B to provide the read-operation address. In some embodiments, the flip-flop 410 provides the read operation address to each GIO circuit and corresponding AND gates.

The GIO controller 118 may receive additional signals to perform its listed functions. For example, the GIO controller 118 may include an input terminal that receives an operation address signal A[0:N]. The operation address signal is provided to the flip-flop 410, where the operation address may be held. The operation address is then provided to the GIO circuits as previously shown. In some embodiments, the GIO controller 118 includes additional input terminals to receive a chip enable (CEB) signal and a write enable (WEB) signal. The input terminals receive the associated signal from an external device connected to the memory device 100.

The repair IO controller 212 includes input terminals that receive a fail column address signal FY[0:1] and a repair IO controller enable signal. The fail column address signal FY[0:1] may be transmitted to one or more of the GIO circuits, such as the GIO circuit 150 and/or the GIO circuit 222, when a repair memory cell is used. In some embodiments, the GIO controller 118 and the repair IO controller 212 may include additional components not shown.

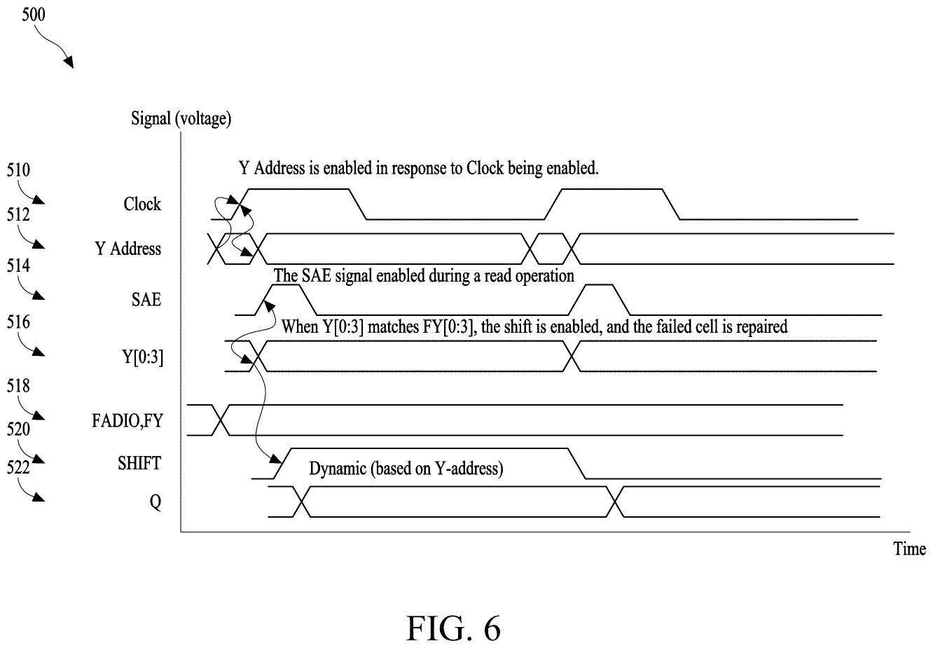

FIG. 6 illustrates a timing diagram 500 showing example signals generated by components within the memory device 100. The timing diagram shows a clock signal 510, a Y address signal 512, a sense amplifier enable (SAE) signal 514, a Y[0:3] address signal 516, a fail column address FY signal 518, a SHIFT signal 520, and a Q signal 522.

The clock signal goes high to start a cycle for an operation, such as a read operation. The Y address signal is enabled responsive to the clock being enabled. The SAE signal is enabled to activate the sense amplifier. The sense amplifier is within the LIO circuit associated with the memory cell that stores the bit that is being read.

Further, the Y[0:3] signal represents the read address being provided to the GIO circuits. In some embodiments, the Y[0:3] is held for a read cycle. Thus, the Y[0:3] signal goes high while a complementary signal goes low when the Y address signal is enabled. Further, the fail column address FY signal 518 goes high while the complementary signal goes low when the Y address is enabled. Responsive to the fail column address FY signal 518 and the Y[0:3] address matching, the SHIFT signal 520 is enabled. In some embodiments, the SHIFT signal 520 is dynamically based on the Y address. In some embodiments, the Q signal 522 represents the output signal of the memory device 100, and the Q signal 522 includes a complementary signal as shown. In some embodiments, additional signals are generated as well.

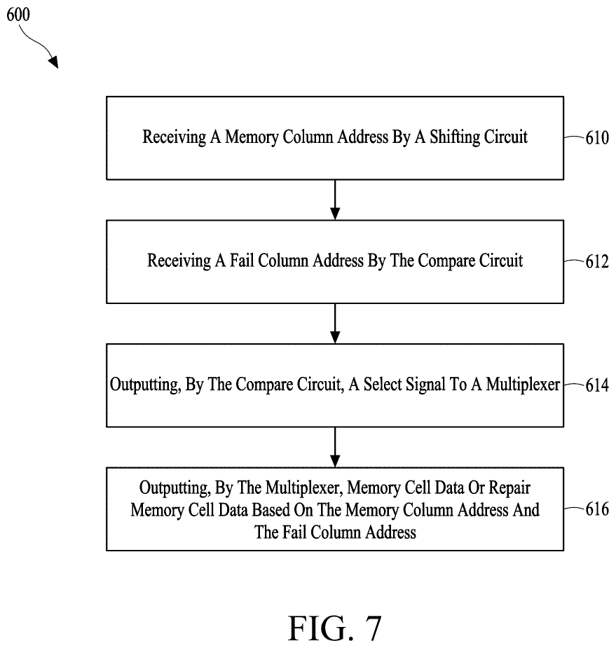

FIG. 7 illustrates an example method 600 for repairing a memory cell. The method 600 includes an operation 610, an operation 612, an operation 614, and an operation 616. In some embodiments, some or all the operations of the method 600 may be performed by some or multiple components of the memory device 100.

At the operation 610, a memory column address is received by a compare circuit. The address signal may be an operation address. The address signal may be provided as the Y[0:3] to the compare circuit 320 of the GIO circuit 150 and the compare circuit 322 of the GIO circuit 222. For example, a bit stored in a memory cell at the address may be being read from the memory device 100. The memory cell may be associated with the GIO circuit 150 of the plurality of GIO circuits. That is, the memory cell provides the bit signal to the LIO circuit 130 with a sense amplifier over a bit line. The LIO circuit provides the read bit to the associated GIO circuit 150 over the global bit line 226. In some embodiments, the address signal is provided from the flip-flop 410 of the GIO controller 118.

At the operation 612, a fail column address is received by the compare circuit. For example, the fail column address signal FY[0:3] may be provided to the compare circuit 320 of the GIO circuit 150 and the compare circuit 322. In some embodiments, the fail column address matches the memory column address. In some embodiments, the fail column address signal is provided from the repair IO controller 212. Further, the AND gate 310A, the AND gate 310B, or both may receive the fail column address and the memory column address at input terminals.

At the operation 614, a select signal is outputted to a multiplexer by the compare circuit. For example, the compare circuit 320 of the GIO circuit 150 or the compare circuit 322 provides a SHIFT signal to the multiplexer 312A or the multiplexer 312B, respectively.

At the operation 616, memory cell data or repair memory cell data is outputted by the multiplexer based on the memory column address and the fail column address. For example, the multiplexer 312B may output data received from the LIO circuit 216 or the repair GIO circuit 224.

In some embodiments, the method 600 is used to shift an output of the first GIO circuit to an adjacent GIO circuit when the fail column address signal and address signal match. For example, the output of the GIO circuit 150 may be shifted to the output of the GIO circuit 222. That is, the output of the multiplexer 312A is the output of the multiplexer 312B. In some embodiments, the multiplexer 312B is shifted to the output of the multiplexer 316 as well. Thus, the output of the GIO circuit 150 is from the repair memory cell associated with the repair GIO circuit 224. In some embodiments, a memory cell associated with the GIO circuit 222 is used to repair. The output from the memory cell associated with the GIO circuit 150 is shifted to the output of the GIO circuit 222. In some embodiments, a number of bits in the address signal is inversely proportional to a number of columns of a redundancy LIO

In some embodiments, the method 600 further includes storing the memory column address in a FF. In some embodiments, the method 600 further includes outputting the memory cell data from a memory LIO responsive to the failed column address not matching the memory column address. In some embodiments, the method 600 further includes outputting the repair memory cell data from a memory LIO circuit responsive to the failed column address matching the memory column address. Further, the memory cell data or the repair memory cell data may be outputted to a second multiplexer.

In some embodiments, the method 600 further includes receiving a HIT signal based on the memory column address and the fail column address matching. The HIT signal and the fail column address may be received from a repair IO controller. The memory column address may be received from a GIO controller. In some embodiments, the method 600 further includes receiving, by the multiplexer, the repair memory cell data. The repair memory cell data may be received from a repair GIO circuit.

In an example embodiment, a memory device includes a repair cell in a repair column having a repair local bit line, a repair local input/output (LIO) circuit having an input connected to the repair local bit line and an output connected to a repair global bit line, and a plurality of memory cells arranged in a first plurality of columns. Each column has a respective memory bit line. The memory device further includes a memory LIO circuit having a plurality of input terminals connected to the respective memory bit lines of the plurality of memory cells and an output terminal connected to a memory global bit line and a first global input/output (GIO) circuit having a first multiplexer with a first input connected to the memory global bit line, a second input connected to receive the output of the repair LIO circuit, an output terminal, and a select signal terminal. The first GIO circuit further includes a first compare circuit having a first input configured to receive a memory column address, a second input configured to receive a fail column address, a third input configured to receive a HIT signal indicating a failed GIO, and an output connected to the select signal terminal. The compare circuit is configured to output the HIT signal based on the memory column address and the fail column address.

In an additional example embodiment, a method includes receiving a memory column address by a compare circuit, receiving a fail column address by the compare circuit, outputting, by the compare circuit, a select signal to a multiplexer, and outputting, by the multiplexer, memory cell data or repair memory cell data based on the memory column address and the fail column address.

In an additional example embodiment, a memory device includes a plurality of global input/output (GIO) circuits. Each of the plurality of GIO circuits includes a multiplexer including a first input connected to at least one LIO circuit through a global bit line, a second input, an output connected to an output buffer of the memory device and, and a select signal terminal, and an AND gate with an output connected to the select signal terminal. The memory device further includes a repair GIO circuit connected to the second input of an adjacent GIO circuit of the plurality of GIO circuits, a flip-flop connected to the input of the AND gate, a fail column address flip-flop connected to the input of the AND gate, and a GIO repair circuit including a multiplexer with an output connected to the input of at least one of the plurality of GIO circuits.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a repair cell in a repair column having a repair local bit line;
a repair local input/output (LIO) circuit having an input connected to the repair local bit line and an output connected to a repair global bit line;
a plurality of memory cells arranged in a first plurality of columns, each column having a respective memory bit line;
a memory LIO circuit having a plurality of input terminals connected to the respective memory bit lines of the plurality of memory cells and an output terminal connected to a memory global bit line; and
a first global input/output (GIO) circuit having:
a first multiplexer with a first input connected to the memory global bit line, a second input connected to receive the output of the repair LIO circuit, an output terminal, and a select signal terminal, and
a first compare circuit having a first input configured to receive a memory column address, a second input configured to receive a fail column address, a third input configured to receive a HIT signal indicating a failed GIO, and an output connected to the select signal terminal, wherein the compare circuit is configured to output the HIT signal based on the memory column address and the fail column address.

2. The memory device of claim 1, wherein the compare circuit includes:
an AND gate with one or more input terminals and an output terminal connected to the select signal terminal.

3. The memory device of claim 1, wherein the multiplexer is configured to output a signal from the memory LIO responsive to the fail column address not matching the memory column address.

4. The memory device of claim 1, further comprising:
a repair GIO circuit with an input terminal connected to the repair LIO circuit and an output terminal connected to the multiplexer of the first GIO circuit.

5. The memory device of claim 4, wherein the multiplexer is configured to output a signal from the repair GIO circuit responsive to the fail column address matching the memory column address.

6. The memory device of claim 5, further comprising:
a second memory GIO circuit including:
a second multiplexer with a first input connected to a second global bit line, a second input connected to the output of the multiplexer of the first memory GIO circuit, an output terminal, and a select signal terminal; and
a second compare circuit having a first input configured to receive the memory column address, a second input configured to receive the fail column address, a third input configured to receive the HIT signal indicating the failed GIO, and an output connected to the select signal terminal, wherein the compare circuit is configured to output the HIT signal based on the memory column address and the fail column address.

7. The memory device of claim 6, wherein the second multiplexer receives a data signal from the multiplexer of the first GIO circuit.

8. The memory device of claim 1, wherein the AND gate of the first memory GIO circuit receives the memory column address from a flip-flop and the fail column address from the fail column address flip-flop.

9. The memory device of claim 8, further comprising:
a GIO controller with the flip-flop connected to the first memory GIO circuit; and
a repair input/output (IO) controller with an input connected to the output of the GIO controller, and further including the fail column address flip-flop connected to the memory GIO circuit.

10. A method, comprising:
receiving a memory column address by a compare circuit;
receiving a fail column address by the compare circuit;
receiving a HIT signal indicating a failed GIO by the compare circuit;
based on the memory column address and the fail column address matching;
outputting, by the compare circuit, a select signal to a multiplexer; and
outputting, by the multiplexer, memory cell data or repair memory cell data based on the memory column address, the fail column address, and the HIT signal.

11. The method of claim 10, further comprising:
outputting the memory cell data from a memory LIO responsive to the fail column address not matching the memory column address.

12. The method of claim 10, further comprising:
outputting the repair memory cell data from a memory LIO circuit responsive to the fail column address matching the memory column address.

13. The method of claim 10, wherein the memory cell data or the repair memory cell data is outputted to a second multiplexer.

14. The method of claim 10, wherein the HIT signal and the fail column address are received from a repair IO controller.

15. The method of claim 10, wherein the memory column address is received from a GIO controller.

16. The method of claim 10, further comprising:
receiving, by the multiplexer, the repair memory cell data.

17. The method of claim 16, wherein the repair memory cell data is received from a repair GIO circuit.

18. A memory device, comprising:
a plurality of global input/output (GIO) circuits, each of the plurality of GIO circuits including:
a multiplexer including a first input connected to at least one LIO circuit through a global bit line, a second input, an output connected to an output buffer of the memory device and, and a select signal terminal, and
an AND gate with an output connected to the select signal terminal;
a repair GIO circuit including an output connected to the second input of one of the plurality GIO circuits;
a flip-flop connected to the input of the AND gate; and
a fail column address flip-flop connected to the input of the AND gate.

19. The memory device of claim 18, wherein the repair GIO circuit is associated with four columns or less of memory cells.

20. The memory device of claim 18, wherein the second input of each of the plurality of GIO circuits connects to the output of an adjacent GIO circuit of the plurality of GIO circuits or the output of the repair GIO circuit.
